(19) United States
(12) Patent Application Publication
(10) Pub. No.: US 2014/0151014 A1
(43) Pub. Date: Jun. 5, 2014

(54) SYSTEM AND METHOD FOR REGULATING TEMPERATURE OF ELECTRONIC COMPONENT

(71) Applicant: TELEFONAKTIEBOLAGET L M ERICSSON (PUBL), Stockholm (SE)

(72) Inventor: Yang Zhang, Beijing (CN)

(73) Assignee: TELEFONAKTIEBOLAGET L M ERICSSON (PUBL), Stockholm (SE)

(21) Appl. No.: 13/808,460

(22) PCT Filed: Dec. 5, 2012
(86) PCT No.: PCT/CN2012/085900

§ 371 Date: Jan. 4, 2013

(51) Int. Cl. H05K 7/20

(52) U.S. Cl. CPC H05K 7/20518; H05K 7/20
USPC 165/206; 165/64; 165/104.26; 165/135

(57) ABSTRACT

The invention relates to a system for regulating temperature of an electronic component, the system comprising: a local heater for heating the electronic component; a heat pipe for cooling the electronic component; and a heat sink for dissipating heat from the heat pipe; wherein the electronic component is adhered to an end of the heat pipe, and the heat sink is adhered to another end of the heat pipe. The invention also relates to a method for regulating temperature of an electronic component by the system.

### FIELD OF THE INVENTION

The invention relates to temperature control, especially a system for regulating temperature of an electronic component and a method thereof.

### BACKGROUND OF THE INVENTION

Nowadays, working temperature of some outdoor electronic products is usually from −40° C. to 55° C., but some electronic components can not work well below 0° C.

One way to solve this problem is to install these products in a cabinet with heaters. When the ambient temperature is lower than a set threshold, the heater(s), which is typically some thousands watts, will be triggered to preheat the cabinet to a temperature level (e.g. 5° C.), then the products inside can be powered on to function normally.

Another way is to find the substitute for the sensitive components for low temperature.

The third way is to add a global heater 103 (as shown in FIG. 1, between a PCB 102 and a heat sink 104) into the product 100 itself to heat it up evenly and keep the temperature level. Therefore, the electronic product 100 can be deployed without cabinet. Here ‘global’ means the heater dimension is comparable with the electronic product 100, and heater area covers most of the area where the temperature-sensitive components 101 are location within. When the heater is working, it heats not only the sensitive components 101 but the whole product 100.

However, there are different problems for the previous solutions.

The cabinet solution is not universally applicable, because some products are defined to work alone without cabinet. Stand-alone product without cabinet shielding is more and more preferred by customer today, and it takes more and more dominant market share.

Finding substitute for sensitive components for low temperature can not always be guaranteed due to the current industrial situation.

The global heater solution also has obvious drawbacks. To heat the whole product up, a very high power consumption is needed (e.g. 400 W), which increase the power design difficulty because it almost doubles the power consumption compared with that when there is no heater. No matter where the heater is placed, it thermally insulates the PCB. This is bad, because at higher temperature, it deteriorates cooling performance. The bigger heater makes the product less compact, which is unfavorable in market competition.

There is no perfect solution available so far to tackle with the heating demand for specific sensitive components.

### SUMMARY OF THE INVENTION

It is therefore an object of the invention to provide a system and a method for regulating temperature of an electronic component, which can function normally regardless of low ambient temperature or high internal temperature.

Here, a “low ambient temperature” means an ambient temperature below which the temperature-sensitive electronic component can not function normally; and a “high internal temperature” means an internal temperature of the component above which the temperature-sensitive electronic component can not function normally.

According to a first aspect of the invention, this object is achieved by providing a system for regulating temperature of an electronic component, the system comprising: a local heater for heating the electronic component; a heat pipe for cooling the electronic component; and a heat sink for dissipating heat from the heat pipe; wherein the electronic component is adhered to an end of the heat pipe, and the heat sink is adhered to another end of the heat pipe.

In this way a “hanging” heat pipe is used to thermally insulate the temperature-sensitive electronic components when the ambient temperature is low, and to cool the components when the internal temperature is relatively high.

The term “hanging” represents herein a concept in the field of thermotics rather than in the field of mechanics. That is, in the context of the present application, “hanging” should be understood as being kept in approximate thermal isolation within a thermal system, but should not only be understood as “remaining suspended or fastened to some point above without support from below”. Particularly and operationally, “hanging” can be construed herein as being in touch with something having a thermal conductivity factor as low as possible, or even being in a vacuum.

The phase change (freezing-melting, condensation-evaporation) mechanism of heat pipe is used to realize heating and cooling in the same hardware. When the ambient temperature is equal to or lower than the freezing point of the working substance in the heat pipe, the working substance freezes, and there is no condensation-evaporation circle in the heat pipe any more. The working substance in solid-state has a relatively low thermal conductivity. Then the thermal resistance of the heat pipe goes high due to the low thermal conductivity of the working substance in solid-state. Thus the temperatures of the components get high enough with limited heating power, and the components function at favourable working temperature. When the ambient temperature goes higher than the freezing point of the working substance, the components start to work normally. When the internal temperature is higher than the favourable working temperature of the components, the working substance in the heat pipe melts into liquid and the heat pipe can work normally as a very good heat conductor to cool the components effectively.

In a further embodiment of the system according to the invention, the size of the local heater is comparable with the size of the electronic component. In this way, relatively less power is wasted at low ambient temperature since the local heater only heats the component instead of the whole device.

In a still further embodiment of the system according to the invention, the middle part of the heat pipe in the longitudinal direction of the heat pipe is surrounded by a thermal insulation material. As the middle part of the heat pipe in the longitudinal direction of the heat pipe is surrounded by a thermal insulation material, most of the heat flow will be transmitted by the heat pipe (i.e., by the wall of the heat pipe and the working substance in solid-state), thus the heat can not be transmitted to the ambient easily at a temperature below the freezing point of the working substance.

To further reduce the heat transmitted by the heat pipe when the ambient temperature is low, the heat pipe should be long enough depending on the high thermal conductivity of the wall. Thus the length of the middle part should be about 1-15 cm (preferably, 5 cm) for a wall of the heat pipe with a thickness of 0.5-1 mm. It is to be noted that, when the heat pipe is used for cooling, such an arrangement will not deteriorate the performance of the heat pipe.

In a further embodiment of the system according to the invention, the thermal conductivity factor of the thermal insulation material is lower than 0.1 W/m·K. Preferably, the thermal insulation material is air, extra-fine glass wool, polyethylene foamed plastics, expanded polystyrene or rock wool, etc.

In a still further embodiment of the system according to the invention, the heat pipe is embedded in a groove formed in the heat sink. In this way the dimension of the device can be reduced, since the heat pipe is only required to be in contact with the heat sink in a relatively small region according to the invention.

In a further embodiment of the system according to the invention, the working substance of the heat pipe could be water, acetone, ammonia, ethanol, or wax, etc. This is convenient for different working temperatures of a variety of electronic components. For example, different working substance has different freezing point and boiling point, thus the specific temperature below which the heat can hardly be transmitted by the heat pipe should be different depending on the working substance. And the same goes for the normal operating temperature (i.e., condensation-evaporation circle) of the heat pipe. As can be understood by those skilled in the art, different working substances can be utilized for different range of working temperature of various temperature-sensitive electronic components.

In a still further embodiment of the system according to the invention, a capillary structure is formed on the inner wall of the heat pipe. A capillary structure formed on the inner wall of the heat pipe enables a more rapid operating cycle of the working substance, thus the heat pipe can be more efficient at high temperature.

In a further embodiment of the system according to the invention, the electronic component is surrounded by the local heater. Instead of the local heater being overlapped on the electronic component, the electronic component can be surrounded by the local heater on the lateral side. In this way, the electronic component can be heated more evenly, since the electronic component is typically small in size and can be easily heated by a surrounding local heater. This also helps to reduce the thickness of the device.

In a still further embodiment of the system according to the invention, a thermal conductivity material is arranged between the local heater and the electronic component, and/or a thermal conductivity material is arranged between the electronic component and the heat pipe. In this way, the thermal resistance between the local heater and the electronic component as well as the thermal resistance between the electronic component and the heat pipe can be reduced to be as low as possible. Thus the electronic component can be heated up more effectively at low temperature, and heat flow can be transmitted by the heat pipe more rapidly at high temperature. This improves the performance of the local heater at low temperature as well as the performance of the heat pipe at high temperature.

According to a second aspect of the invention, this object is achieved by providing a method for regulating temperature of an electronic component by a system, wherein the system comprises: a local heater for heating the electronic component; a heat pipe for cooling the electronic component; and a heat sink for dissipating heat from the heat pipe; the method comprising the steps of: adhering the electronic component to an end of the heat pipe, and adhering the heat sink to another end of the heat pipe; heating the electronic component with the local heater when the ambient temperature is lower than a first predetermined value; and dissipating heat from the electronic component with the heat pipe when the internal temperature is higher than a second predetermined value.

A “hanging” configuration of a heat pipe is utilized to realize a thermal insulation function when the ambient temperature is low and to realize a cooling function when the ambient temperature is high. The phase change (freezing-melting, condensation-evaporation) mechanism of heat pipe is used to realize heating and cooling in the same hardware. Below the first predetermined value, the thermal insulation function of the heat pipe will be enabled as described above according to the first aspect of the invention. When the ambient temperature goes higher than the second predetermined value or even higher than the favourable working temperature of the components, the components start to work normally and the cooling function of the heat pipe will be enabled as described above according to the first aspect of the invention. It is to be noted that: when the ambient temperature is higher than the first predetermined value, the temperature-sensitive electronic components can function normally without heating; when the internal temperature is lower than the second predetermined value, the temperature-sensitive electronic components can also function normally without cooling.

In a further embodiment of the method according to the invention, the first predetermined value is substantially equal to or lower than the freezing point of the working substance of the heat pipe to ensure the thermal insulation function of the heat pipe.

In a still further embodiment of the method according to the invention, the second predetermined value is substantially equal to the lowest operating temperature of the heat pipe to ensure the thermal insulation function of the heat pipe.

In a further embodiment of the method according to the invention, the size of the local heater is comparable with the size of the electronic component. In this way, relatively less power is wasted at low temperature since the local heater only heats the component instead of the whole device.

In a still further embodiment of the method according to the invention, the middle part of the heat pipe in the longitudinal direction of the heat pipe is surrounded by a thermal insulation material. As the middle part of the heat pipe in the longitudinal direction of the heat pipe is surrounded by a thermal insulation material, most of the heat flow will be transmitted by the heat pipe, thus the heat can not be transmitted to the ambient easily at a temperature below the freezing point of the working substance.

In a further embodiment of the method according to the invention, the thermal conductivity factor of the thermal insulation material is lower than 0.1 W/m·K. Preferably, the thermal insulation material is air, extra-fine glass wool, polyethylene foamed plastics, expanded polystyrene or rock wool, etc.

In a still further embodiment of the method according to the invention, the heat pipe is embedded in a groove formed in the heat sink. In this way the dimension of the device can be reduced, since the heat pipe is only required to be in contact with the heat sink in a relatively small region according to the invention.

In a further embodiment of the method according to the invention, the working substance of the heat pipe could be water, acetone, ammonia, ethanol, or wax, etc. This is convenient for different working temperatures of a variety of electronic components. For example, different working substance has different freezing point and boiling point, thus the specific temperature below which the heat can hardly be transmitted by the heat pipe should be different depending on the working substance. And the same goes for the normal operating temperature (i.e., condensation-evaporation circle) of the heat pipe.

In a still further embodiment of the method according to the invention, a capillary structure is formed on the inner wall of the heat pipe. A capillary structure formed on the inner wall of the heat pipe enables a more rapid operating cycle of the working substance, thus the heat pipe can be more efficient at high temperature.

In a further embodiment of the method according to the invention, the electronic component is surrounded by the local heater. Instead of the local heater being overlapped on the electronic component, the electronic component can be surrounded by the local heater on the lateral side. In this way, the electronic component can be heated more evenly, since the electronic component is typically small in size and can be easily heated by a surrounding local heater. This also helps to reduce the thickness of the device.

In a still further embodiment of the method according to the invention, a thermal conductivity material is arranged between the local heater and the electronic component, and/or a thermal conductivity material is arranged between the electronic component and the heat pipe. In this way, the thermal resistance between the local heater and the electronic component as well as the thermal resistance between the electronic component and the heat pipe can be reduced to be as low as possible. Thus the electronic component can be heated up more effectively at low ambient temperature, and heat flow can be transmitted by the heat pipe more rapidly at high internal temperature. This improves the performance of the local heater at low ambient temperature as well as the performance of the heat pipe at high internal temperature.

With local heater and/or such a “hanging” configuration as described above, the present invention is applicable for a wide range of outdoor electronic products. The local heater can save power by hundreds watts during cold start and low-temperature operation (which relaxes the requirement for power design, and reduces the cost of power hardware), and even reduce the cost compared with the traditional global heater. The “hanging” configuration of the heat pipe improves both the thermal insulation function at low ambient temperature and the cooling function at high internal temperature.

### BRIEF DESCRIPTION OF THE DRAWINGS

The above and other, more detailed aspects of the invention will be s elucidated and described hereinafter, by way of example, with reference to the accompanying drawing wherein

FIG. 1 shows a section view of a prior art electronic device with a global heater and a diagrammatic front view of the global heater;

FIG. 2A shows a diagrammatic front view of an embodiment of the local heaters according to the invention;

FIG. 2B shows a section view of an embodiment of the system for regulating temperature of electronic components according to the invention;

FIG. 3 shows a section view of another embodiment of the system for regulating temperature of electronic components according to the invention.

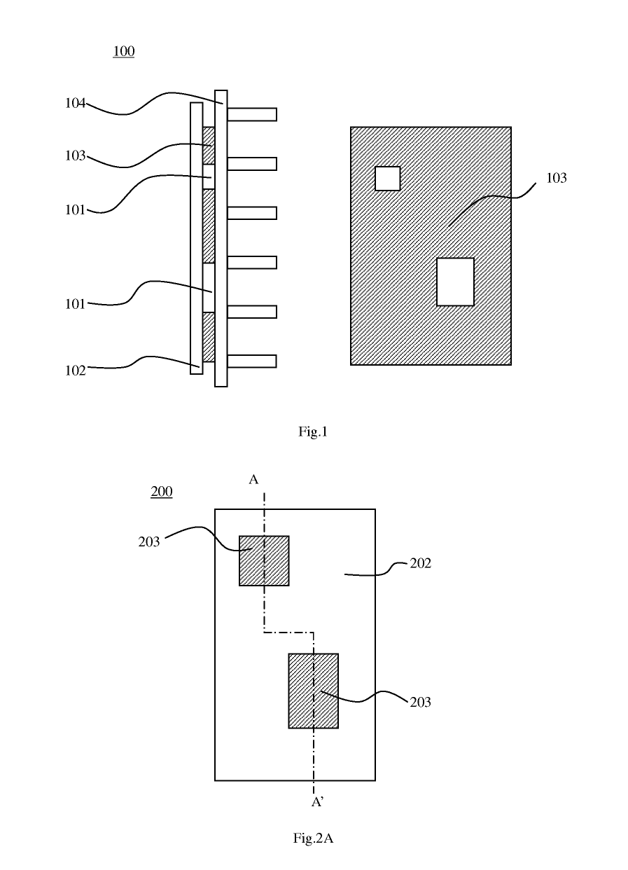

### DETAILED DESCRIPTION OF EMBODIMENTS

FIG. 2A shows a diagrammatic front view of an embodiment of the local heaters according to the invention; and FIG. 2B shows a section view of an embodiment of the system for regulating temperature of electronic components according to the invention; FIG. 2B is taken along the A-A′ line of FIG. 2A. The system 200 comprises temperature-sensitive electronic components 201, which are bonded to a print circuit board (PCB) 202. The local heaters 203 are located on the PCB 202; and each of the local heaters 203 corresponds to a temperature-sensitive electronic component 201. The PCB 202 is located on a side of the electronic components 201. Heat pipes 204 for cooling the electronic components 201 are located on the other side of the electronic components 201. The system 200 is arranged such that each electronic component 201 is adhered to an end of the heat pipe 204a (as the hot end of the heat pipe 204), and a heat sink 205 is adhered to another end of the heat pipe 204c (as the cold end of the heat pipe 204). Since two electronic components 201 (as shown in the figures) can be arranged in the system 200 with the same configuration, the structure of the system 200 will be introduced with reference to one of these electronic components 201.

With such a configuration, the heat pipe 204 with a “hanging” configuration is used to thermally insulate the temperature-sensitive electronic components at low ambient temperature, and to cool the components at high internal temperature, as will be described in detail hereinafter.

The phase change (freezing-melting, condensation-evaporation) mechanism of heat pipe is used to realize heating and cooling in the same hardware. When the ambient temperature is equal to or lower than the freezing point of the working substance (not shown) in the heat pipe 204, the working substance freezes, and there is no condensation-evaporation circle in the heat pipe 204 any more. The working substance in solid-state has a relatively low thermal conductivity. Then the thermal resistance of the heat pipe 204 goes high due to the low thermal conductivity of the working substance in solid-state. Thus the temperatures of the components 201 get high enough with limited heating power, and the components function at favourable working temperature. On the other hand, when the ambient temperature goes higher than the freezing point of the working substance, the component 201 starts to work normally. When the internal temperature is higher than the favourable working temperature of the electronic component 201, the working substance in the heat pipe 204 melts into liquid and the heat pipe 204 can work normally as a very good heat conductor to cool the component 201 effectively.

Take a commonly used copper-water heat pipe for example. The wall of the heat pipe is made of copper and the working substance inside is water. Below 0° C., water will freeze into ice, which has a very low thermal conductivity. So the thermal resistance of the heat pipe 204 is relatively high, and the component 201 can enjoy a favourable working temperature with a limited heating power. When the ambient temperature goes higher than 0° C., the component 201 start to work normally, and the ice melts into liquid. As the internal temperature goes higher (e.g. higher than 30° C., or even higher than 50° C)., the heat pipe 204 can work normally as a very good heat conductor to cool the component 201 effectively.

The size of the local heater 203 is preferably comparable with the size of the electronic component 201, which means the size of the local heater 203 can be designed as small as possible. In this way, relatively less power is wasted at low ambient temperature since the local heater 203 only heats the component 201 instead of the whole device.

Preferably, the middle part 204b of the heat pipe in the longitudinal direction of the heat pipe 204 is surrounded by a thermal insulation material 206. As the middle part 204b of the heat pipe in the longitudinal direction of the heat pipe 204 is surrounded by a thermal insulation material 206, most of the heat flow will be transmitted by the heat pipe is 204 (i.e., by the wall of the heat pipe and the working substance in solid-state), thus the heat can not be transmitted to the ambient easily at an ambient temperature below the freezing point of the working substance, as described above.

To further reduce the heat transmitted by the heat pipe when the ambient temperature is low, the heat pipe should be long enough depending on the high thermal conductivity of the wall. Thus the length of the middle part should be about 1-15 cm (preferably, 5 cm) for a wall of the heat pipe with a thickness of 0.5-1 mm. It is to be noted that, when the heat pipe is used for cooling, such an arrangement will not deteriorate the performance of the heat pipe.

In a further embodiment of the system 200 according to the invention, the thermal conductivity factor of the thermal insulation material 206 is lower than 0.1 W/m·K. Preferably, the thermal insulation material is air, extra-fine glass wool, polyethylene foamed plastics, expanded polystyrene or rock wool, etc. Thermal insulation material with a low thermal conductivity factor makes it almost impossible for the heat flow to be transmitted via other heat path but the heat pipe 204. Therefore, the heating performance of the local heater 203 at low ambient temperature can be ensured.

In a still further embodiment of the system 200 according to the invention, the heat pipe 204 is embedded in a groove 207 formed in the s heat sink 205. In this way the dimension of the device can be reduced, since the heat pipe 204 is only required to be in contact with the heat sink 205 in a relatively small region (i.e., the cold end 204c of the heat pipe 204) according to the invention.

Preferably, the working substance of the heat pipe 204 could be water, acetone, ammonia, ethanol, or wax, etc. This is convenient for different working temperatures of a variety of electronic components. For example, different working substance has different freezing point and boiling point, thus the specific temperature below which the heat can hardly be transmitted by the heat pipe should be different depending on the working substance. And the same goes for the normal operating temperature (i.e., condensation-evaporation circle) of the heat pipe. The range of working temperature of different working substance is listed below in table 1.

TABLE 1

| Working | Melting point | Boiling point | Range of working temperature |
|---|---|---|---|
| substance | ° C. | ° C. | ° C. |
| methane | −184 | −161 | −173~−100 |
| ammonia | −78 | −33 | −60~100 |
| freon 21 | −135 | 9 | −103~127 |
| freon 11 | −111 | 24 | −40~120 |
| pentane | −130 | 28 | −20~120 |
| freon 113 | −35 | 48 | −10~100 |
| acetone | −95 | 57 | 0~120 |
| methanol | −98 | 64 | 10~130 |
| ethanol | −114 | 78 | 0~130 |
| heptanol | −90 | 98 | 0~150 |
| water | 0 | 100 | 30~200 |

In a still further embodiment of the system 200 according to the invention, a capillary structure (not shown) is formed on the inner wall of the heat pipe 204. Since capillary structure provides capillary force for transporting the condensate working substance back to the hot end of the s heat pipe (i.e., condensation-evaporation circle), a capillary structure formed on the inner wall of the heat pipe 204 enables a more rapid operating cycle of the working substance, thus the heat pipe 204 can be more efficient at high internal temperature.

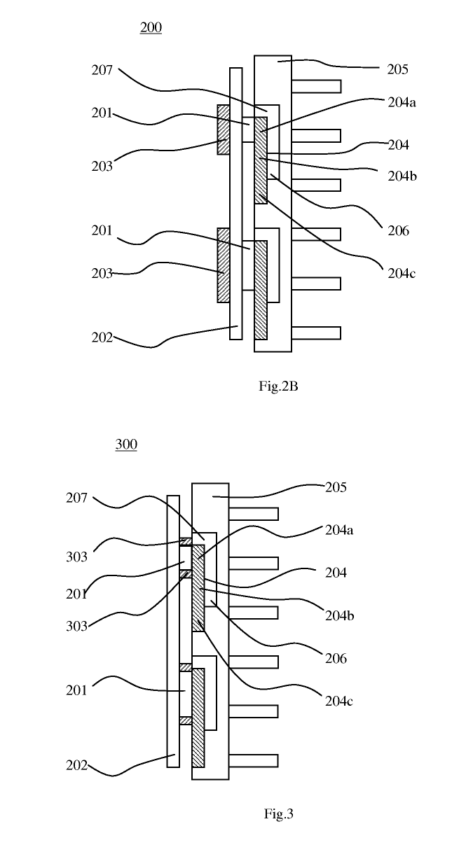

FIG. 3 shows a section view of another embodiment of the system 300 for regulating temperature of electronic components 201 according to the invention. In the embodiment of the system 300 according to the invention, the electronic component 201 is surrounded by a local heater 303. Instead of the local heater being overlapped on the electronic component, the electronic component 201 is surrounded by the local heater 303 on the lateral side. Preferably, a flexible material for heating can be applied around the component as a local heater. In this way, the electronic component 201 can be heated more evenly, since the electronic component 201 is typically small in size and thus can be easily heated by a surrounding local heater 303. This also helps to reduce the thickness of the system 300 and make the device more compact.

In a still further embodiment of the system 200, 300 according to the invention, a thermal conductivity material (not shown) is arranged between the local heater 203, 303 and the electronic component 201, and/or a thermal conductivity material (not shown) is arranged between the electronic component 201 and the heat pipe 204. In this way, the thermal resistance between the local heater 203, 303 and the electronic component 201 as well as the thermal resistance between the electronic component 201 and the heat pipe 204 can be reduced to be as low as possible. Thus the electronic component 201 can be heated up more effectively at low ambient temperature, and heat flow can be transmitted by the heat pipe 204 more rapidly at high internal temperature. This improves the performance of the local heater 203, 303 at low ambient temperature as well as the performance of the heat pipe 204 at high internal temperature.

Though the electronic components 201 are bonded to a PCB 202 in the embodiments described in reference with the drawings, the electronic components 201 can also be connected to a power source or other s components with other suitable means, such as flexible circuit board, wire bonding, metal bridge, etc.

According to a second aspect of the invention, there is provided a method for regulating temperature of an electronic component 201 by a system, wherein the system comprises: a local heater 203, 303 for heating the electronic component 201; a heat pipe 204 for cooling the electronic component 201; and a heat sink 205 for dissipating heat from the heat pipe 204; the method comprising the steps of: adhering the electronic component 201 to an end of the heat pipe 204, and adhering the heat sink 205 to another end of the heat pipe 204; heating the electronic component 201 with the local heater 203, 303 when the ambient temperature is lower than a first predetermined value; and dissipating heat from the electronic component 201 with the heat pipe 204 when the internal temperature is higher than a second predetermined value.

To ensure the thermal insulation function of the heat pipe 204 as described above, the first predetermined value can be set as substantially equal to or lower than the freezing point of the working substance of the heat pipe 204. To ensure the cooling function of the heat pipe 204 as described above, the second predetermined value can be set as substantially equal to the lowest operating temperature of the heat pipe. Take a commonly used copper-water heat pipe for example, the first predetermined value can be set as 0° C. or a lower value, the second predetermined value is 30° C. (which is the lowest operating temperature of the heat pipe as shown in Table 1).

According to the embodiments of the invention, the “hanging” configuration of the heat pipe is necessary to increase thermal resistance as the ambient temperature is low, and the heat pipe can also function normally to cool down the component as the internal temperature is relatively high.

It is to be noted that the temperature-sensitive electronic components can also function normally when the temperature of the component is between the first predetermined value and the second predetermined value since such a range per se is the normal range of working temperature.

With local heater and/or such a “hanging” configuration as described above, the present invention is applicable for a wide range of outdoor electronic products. The local heater can save power by hundreds watts during cold start and low-temperature operation (which relaxes the requirement for power design, and reduces the cost of power hardware), and even reduce the cost compared with the traditional global heater. The “hanging” configuration of the heat pipe improves both the thermal insulation function at low ambient temperature and the cooling function at high internal temperature.

As can be understood by those skilled in the art, component 201 should not be limited to be a single component, but could also be understood to comprise several temperature-sensitive elements that are located near to each other and hence can be served by a common local heater as well as a common heat pipe.

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage. Any reference signs in the claims should not be construed as limiting the scope.

1. A system for regulating temperature of an electronic component, the system comprising
a local heater for heating the electronic component;
a heat pipe for cooling the electronic component; and
a heat sink for dissipating heat from the heat pipe;
wherein the electronic component is adhered to an end of the heat pipe, and the heat sink is adhered to another end of the heat pipe.

2. The system according to claim 1, wherein the size of the local heater is comparable with the size of the electronic component.

3. The system according to claim 1, wherein the middle part of the heat pipe in the longitudinal direction of the heat pipe is surrounded by a thermal insulation material.

4. The system according to claim 1, wherein the length of the middle part is between 1-15 cm for a wall of the heat pipe with a thickness of 0.5-1 mm.

5. The system according to claim 1, wherein the thermal conductivity factor of the thermal insulation material is lower than 0.1 W/m·K.

6. The system according to claim 1, wherein the thermal insulation material is air, extra-fine glass wool, polyethylene foamed plastics, expanded polystyrene or rock wool.

7. The system according to claim 1, wherein the heat pipe is embedded in a groove formed in the heat sink.

8. The system according to claim 1, wherein the working substance of the heat pipe is water, acetone, ammonia, ethanol, or wax.

9. The system according to claim 1, wherein a capillary structure is formed on the inner wall of the heat pipe.

10. The system according to claim 1, wherein the electronic component is surrounded by the local heater.

11. The system according to claim 1, wherein a thermal conductivity material is arranged between the local heater and the electronic component.

12. The system according to claim 1, wherein a thermal conductivity material is arranged between the electronic component (201) and the heat pipe (204).

13. The system according to claim 1, wherein the electronic component comprises several temperature-sensitive elements located near to each other.

14. A method for regulating temperature of an electronic component by a system, wherein the system comprises
a local heater for heating the electronic component;
a heat pipe for cooling the electronic component; and
a heat sink for dissipating heat from the heat pipe;
the method comprising the steps of:
adhering the electronic component to an end of the heat pipe, and adhering the heat sink to another end of the heat pipe;
heating the electronic component with the local heater when the ambient temperature is lower than a first predetermined value; and
dissipating heat from the electronic component with the heat pipe when the internal temperature is higher than a second predetermined value.

15. The method according to claim 14, wherein the first predetermined value is substantially equal to or lower than the freezing point of the working substance of the heat pipe.

16. The method according to claim 1, wherein the second predetermined value is substantially equal to the lowest operating temperature of the heat pipe.

17. The method according to claim 1, wherein the size of the local heater is comparable with the size of the electronic component.

18. The method according to claim 1, wherein the middle part of the heat pipe in the longitudinal direction of the heat pipe is surrounded by a thermal insulation material.

19. The method according to claim 1, wherein the length of the middle part is between 1-15 cm for a wall of the heat pipe with a thickness of 0.5-1 mm.

20. The method according to claim 1, wherein the thermal conductivity factor of the thermal insulation material is lower than 0.1 W/m·K.

21. The method according to claim 1, wherein the thermal insulation material is air, extra-fine glass wool, polyethylene foamed plastics, expanded polystyrene or rock wool.

22. The method according to claim 1, wherein the heat pipe is embedded in a groove formed in the heat sink.

23. The method according to claim 1, wherein the working substance of the heat pipe is water, acetone, ammonia, ethanol, or wax.

24. The method according to claim 1, wherein a capillary structure is formed on the inner wall of the heat pipe.

25. The method according to claim 1, wherein the electronic component is surrounded by the local heater.

26. The method according to claim 1, wherein a thermal conductivity material is arranged between the local heater and the electronic component.

27. The method according to claim 1, wherein a thermal conductivity material is arranged between the electronic component and the heat pipe.

28. The method according to claim 1, wherein the electronic component comprises several temperature-sensitive elements located near to each other.
